(19) United States
(12) Patent Application Publication
(10) Pub. No.: US 2018/0204982 A1
(43) Pub. Date: Jul. 19, 2018

(54) LIGHT EMITTING ELEMENT PACKAGE

(71) Applicant: LG INNOTEK CO., LTD., Seoul (KR)

(72) Inventors: Suk Kyung PARK, Seoul (KR); Dong Yong LEE, Seoul (KR)

(21) Appl. No.: 15/752,329

(22) PCT Filed: Aug. 12, 2016
(86) PCT No.: PCT/KR2016/008927

§ 371 Date: Feb. 13, 2018

(30) Foreign Application Priority Data
Aug. 13, 2015 (KR) 10-2015-0114769

(51) Int. Cl. H01L 33/40; H01L 33/50; H01L 33/60

(52) U.S. Cl. CPC H01L 33/405; H01L 2933/0016; H01L 33/60; H01L 33/50

(57) ABSTRACT

An embodiment discloses a light emitting element package including: a light emitting element including first and second electrode pads disposed on one surface thereof; a wavelength conversion layer disposed on the other surface of the light emitting element; and a reflective wall disposed on a side surface of the light emitting element, wherein the reflective wall is in contact with the side surface of the light emitting element, and the first and second electrode pads are exposed to the outside.

### TECHNICAL FIELD

The present invention relates to a light emitting element package.

### BACKGROUND ART

A light emitting diode (LED) device is a compound semiconductor device that converts electrical energy into light energy. The LED may implement various colors by adjusting a composition ratio of a compound semiconductor.

A nitride semiconductor LED has advantages, such as lower energy consumption, semi-permanent lifespan, rapid response speed, stability, and environmental friendliness, when compared to existing light sources such as a fluorescent lamp and an incandescent lamp. Accordingly, an application range of the nitride semiconductor LED has been extended to an LED backlight capable of replacing a cold cathode fluorescent lamp (CCFL) constituting a backlight of a liquid crystal display (LCD) device, a white LED lighting device capable of replacing a fluorescent lamp or an incandescent lamp, a vehicle headlight, and a signal lamp.

A chip scale package (CSP) may be manufactured by directly forming a fluorescent layer on a flip chip. The CSP may ensure miniaturization of a package. However, in order to increase an amount of light incident on a light guide plate and the like, there is a need to adjust an orientation angle of the CSP.

### TECHNICAL PROBLEM

According to exemplary embodiments, it is possible to adjust an orientation angle of a chip scale package (CSP).

In addition, it is possible to improve a luminous flux of a CSP.

### Technical Solution

One aspect of the present invention provides a light emitting element package including: a light emitting element including a first electrode pad and a second electrode pad disposed on one surface thereof; a wavelength conversion layer disposed on the other surface of the light emitting element; and a reflective wall disposed on a side surface of the light emitting element, wherein the reflective wall is in contact with the side surface of the light emitting element, and the first electrode pad and the second electrode are exposed to the outside.

The wavelength conversion layer may be disposed on the reflective wall.

The reflective wall may have a first surface in contact with the wavelength conversion layer and a second surface opposite the first surface.

The second surface may be convex toward the first surface.

The light emitting element package may further include a diffusion layer disposed on the wavelength conversion layer.

A width in a second direction of the reflective wall may be greater than a width in a first direction of the wavelength conversion layer, the first direction may be parallel to a thickness direction of the light emitting element, and the second direction may be perpendicular to the first direction.

A width in a first direction of the reflective wall may be greater than a width in the first direction of the wavelength conversion layer, and the first direction may be parallel to a thickness direction of the light emitting element.

The reflective wall may be in contact with a side surface of the wavelength conversion layer.

An uneven portion may be formed on a contact surface between the wavelength conversion layer and the reflective wall.

The wavelength conversion layer may have a thickness of 0.05 mm to 0.1 mm.

The reflective wall may have a thickness of 0.2 mm to 0.5 mm.

The reflective wall may include phenyl silicone or methyl silicone.

The reflective wall may include reflective particles.

Another aspect of the present invention provides a light emitting element package including: a light emitting element including a first electrode pad and a second electrode pad disposed on one surface thereof; a wavelength conversion layer disposed on the other surface and a side surface of the light emitting element; and a reflective wall disposed on a side surface of the wavelength conversion layer, wherein the first electrode pad and the second electrode are exposed to the outside.

A side thickness of the wavelength conversion layer may be gradually increased from the one surface of the light emitting element to the other surface thereof.

The reflective wall may be gradually thinner from the one surface of the light emitting element to the other surface thereof

The reflective wall may have an inclined surface formed on an inner peripheral surface thereof.

The reflective wall may have a lower inclined surface having a first inclination angle and an upper inclined surface having a second inclination angle.

The first inclined angle may be greater than the second inclined angle.

The first inclined angle may be equal to the second inclined angle.

### Advantageous Effects

According to exemplary embodiments, it is possible to adjust an orientation angle of a chip scale package (CSP).

In addition, it is possible to improve a luminous flux of a CSP.

The various advantageous advantages and effects of the present invention are not limited to the above description, and may be more easily understood in the course of describing a specific exemplary embodiment of the present invention.

### DESCRIPTION OF DRAWINGS

FIG. 1 is a perspective view illustrating a light emitting element package according to a first exemplary embodiment.

FIG. 2 is a cross-sectional view taken along line A-A.

FIG. 3 is a view illustrating a modified example of FIG. 2.

FIG. 4 is a cross-sectional view illustrating a light emitting element package according to a second exemplary embodiment of the present invention.

FIG. 5 is a view illustrating a modified example of the light emitting element package of FIG. 4.

FIG. 6 is a perspective view illustrating a light emitting element package according to a third exemplary embodiment of the present invention.

FIG. 7 is a cross-sectional view illustrating a light emitting element package according to a fourth exemplary embodiment of the present invention.

FIG. 8 is a cross-sectional view illustrating a light emitting element according to an exemplary embodiment of the present invention.

FIGS. 9A to 9D are a flowchart of a method of manufacturing the light emitting element package according to the first exemplary embodiment of the present invention.

FIGS. 10A to 10E are a flowchart of a method of manufacturing the light emitting element package according to the second exemplary embodiment of the present invention.

FIG. 11 is a view illustrating a method of manufacturing the light emitting element package according to the third exemplary embodiment of the present invention.

FIGS. 12A to 12E are a flowchart of a method of manufacturing the light emitting element package according to the fourth exemplary embodiment of the present invention.

### MODES OF THE INVENTION

While the present invention is open to various modifications and alternative embodiments, specific embodiments thereof will be described and shown by way of example in the drawings. However, it should be understood that there is no intention to limit the present invention to the particular embodiments disclosed, and, on the contrary, the present invention is to cover all modifications, equivalents, and alternatives falling within the spirit and scope of the present invention.

It should be understood that, although the terms including ordinal numbers such as “first,” “second,” and the like may be used herein to describe various elements, the elements are not limited by the terms. The terms are only used to distinguish one element from another. For example, a second element could be termed a first element without departing from the teachings of the present inventive concept, and similarly a first element could be also termed a second element. The term “and/or” includes any and all combination of one or more of the associated items listed.

The terminology used herein is for the purpose of describing particular embodiments only and is not intended to limit the present inventive concept. As used herein, the singular forms “a,” “an,” and “the” are intended to include the plural forms as well, unless the context clearly indicates otherwise. It should be further understood that the terms “comprises” and/or “comprising” used in this specification, specify the presence of stated features, integers, steps, operations, elements, and/or components, but do not preclude the presence or addition of one or more other features, integers, steps, operations, elements, components, and/or groups thereof.

It should be understood that, when an element is referred to as being “on” or “under” another element, the element may be directly on/under the other element, and/or one or more intervening elements may also be present. When an element is referred to as being “on” or “under” another element, the meaning thereof may include the element being “on the other element” as well as being “under the other element.”

Hereinafter, example embodiments will be described with reference to the attached drawings, and the same or corresponding elements will be given the same reference numbers regardless of drawing symbols, and overlapping descriptions will be omitted.

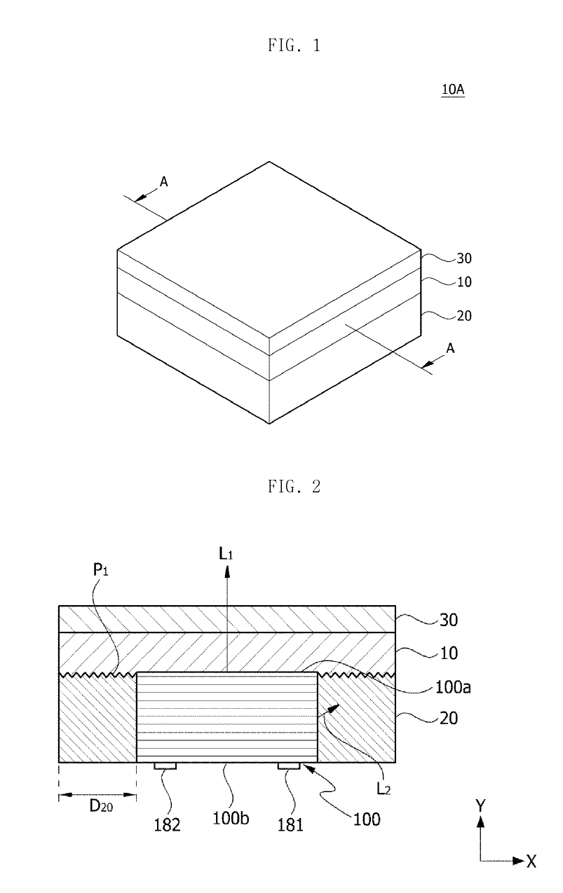

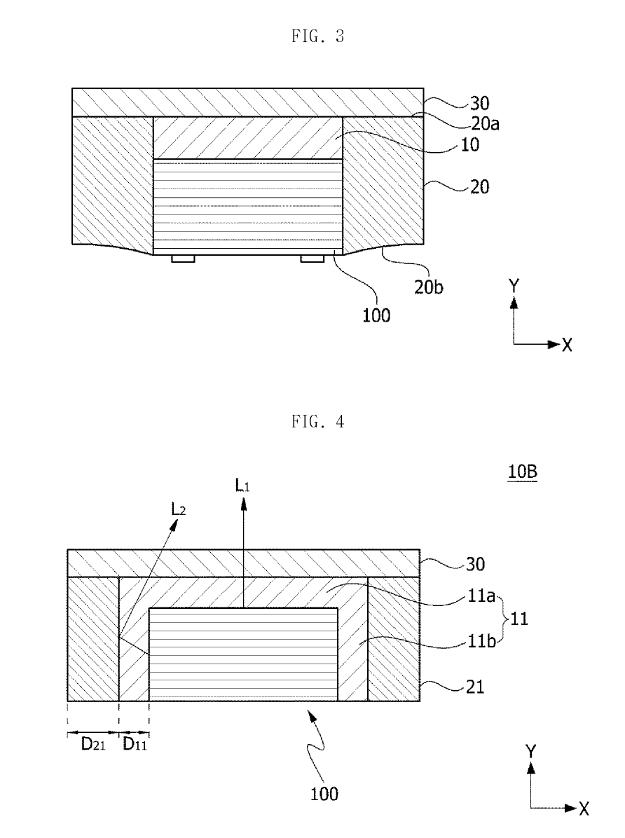

FIG. 1 is a perspective view illustrating a light emitting element package according to a first exemplary embodiment, FIG. 2 is a cross-sectional view taken along line A-A, and FIG. 3 is a view illustrating a modified example of FIG. 2.

Referring to FIGS. 1 and 2, a light emitting element package 10A according to the exemplary embodiment includes a light emitting element 100, a wavelength conversion layer 10 covering one surface 100a of the light emitting element 100, and a reflective wall 20 covering side surfaces of the light emitting element 100. The light emitting element package may be a chip scale package (CSP).

First light L1 emitted from the one surface of the light emitting element 100 may be converted into white light by the wavelength conversion layer 10, and second light L2 emitted from the side surfaces of the light emitting element 100 may be blocked by the reflective wall 20.

The light emitting element 100 may emit light in an ultraviolet wavelength range or light in a blue wavelength range. The present invention is not necessarily limited thereto, and the light emitting element 100 may generate light in various wavelength ranges. The light emitting element 100 may be a flip chip including first and second electrode pads 181 and 182 disposed on the other surface 100b thereof. The first and second electrode pads 181 and 182 may be exposed to the outside and mounted on a circuit board (not shown) or the like. A structure of the light emitting element 100 will be described below.

The wavelength conversion layer 10 may cover the one surface of the light emitting element 100. An uneven portion P1 may be formed on a boundary surface between the wavelength conversion layer 10 and the reflective wall 20. A binding force between the wavelength conversion layer 10 and the reflective wall 20 may be improved by the uneven portion P1. The uneven portion P1 may be formed by forming an uneven pattern on the reflective wall and forming the wavelength conversion layer on the uneven pattern. The wavelength conversion layer 10 may have a thickness of 0.05 mm to 0.1 mm, but the present invention is not limited thereto.

The wavelength conversion layer 10 may be made of a polymer resin. The polymer resin may be at least one selected from a light-transmitting epoxy resin, a silicone resin, a polyimide resin, a urea resin, and an acrylic resin. In an example, the polymer resin may be a silicone resin.

Wavelength conversion particles dispersed in the wavelength conversion layer 10 may absorb light emitted from the light emitting element 100 and convert the absorbed light into white light. For example, the wavelength conversion particle may include at least one selected from a fluorescent material and a quantum dot (QD). The following descriptions assume that the wavelength conversion particle is a fluorescent material.

The fluorescent material may include any one selected from a YAG-based fluorescent material, a TAG-based fluorescent material, a silicate-based fluorescent material, a sulfide-based fluorescent material, and a nitride-based fluorescent material, but exemplary embodiments are not limited in a kind of the fluorescent material.

The YAG-based and TAG-based fluorescent materials may be selected from materials satisfying (Y, Tb, Lu, Sc, La, Gd, Sm)3(Al, Ga, In, Si, Fe)5(O, S)12:Ce. The silicate-based fluorescent material may be selected from materials satisfying (Sr, Ba, Ca, Mg)2SiO4:(Eu, F, Cl).

In addition, the sulfide-based fluorescent material may be selected from materials satisfying (Ca, Sr)S:Eu and (Sr, Ca, Ba) (Al, Ga)2S4:Eu. The nitride-based fluorescent material may be selected from materials satisfying (Sr, Ca, Si, Al, O)N:Eu (for example, CaAlSiN4:Eu or β-SiAlON:Eu), or materials satisfying Ca-α SiAlON:Eu-based (Cax, My) (Si, Al)12(O, N)16, wherein M may be at least one selected from Eu, Tb, Yb, and Er and may be selected from fluorescent components satisfying 0.05<(x+y)<0.3, 0.02<x<0.27, and 0.03<y<0.3.

A red fluorescent material may be a nitride-based fluorescent material including N (for example, CaAlSiN3:Eu) or a K2SiF6 (KSF) fluorescent material.

The reflective wall 20 reflects side surface light L2 of the light emitting element 100. Reflected light may be incident on the light emitting element 100 or may be emitted to the one surface of the light emitting element 100. Therefore, it is possible to adjust an orientation angle and a distribution pattern of the light emitting element package. A thickness D20 of the reflective wall may be in a range of 0.2 mm to 0.5 mm.

The reflective wall 20 may include a material capable of reflecting light. In an example, the reflective wall 20 may include at least one selected from phenyl silicone and methyl silicone. In addition, the reflective wall 20 may include reflective particles. In an example, the reflective wall may be a glass in which TiO2 is dispersed.

Here, a lower surface of the reflective wall 20 may be coplanar with the other surface of the light emitting element 100. Therefore, the first and second electrode pads 181 and 182 may be disposed at a lower level than the lower surface of the reflective wall 20. Such a structure may have an advantage in mounting a package.

However, the present invention is not necessarily limited thereto, and the reflective wall 20 may extend to the other surface of the light emitting element 100. In this case, the lower surfaces of the first and second electrode pads 181 and 182 may pass through the reflective wall 20 and may be exposed to the outside.

Referring to FIG. 3, the reflective wall 20 may have a first surface 20a in contact with the wavelength conversion layer 10 and a second surface 20b opposite the first surface 20a. Any one of the first surface 20a and the second surface 20b may have a convex or concave shape. The convex or concave shape may be formed when the reflective wall 20 wall is cured. In an example, the second surface 20b may be formed convexly toward the first surface 20a.

The reflective wall 20 may be formed to have a height greater than a height of the light emitting element 100. That is, a width in a first direction of the reflective wall 20 may be greater than a width in the first direction of the light emitting element 100. Here, the height may be defined as the width in the first direction (Y-direction) parallel to a thickness direction of the light emitting element. The height of the reflective wall may be adjusted to maintain an orientation angle corresponding to a field of view (FOV) of a camera. Therefore, it is possible to control light loss generated as the orientation angle becomes too wide. In an example, when a FOV of a camera is an angle of 75°, the height of the reflective wall 20 may be appropriately adjusted to maintain an orientation angle corresponding to the FOV of the camera.

A diffusion layer 30 is disposed on the wavelength conversion layer 10 to diffuse light. The diffusion layer 30 may have any configuration of a general diffusion layer. In an example, the diffusion layer 30 may be formed by attaching a separate diffusion film or may be formed through spraying. Separate scattering particles may be dispersed in the diffusion layer 30.

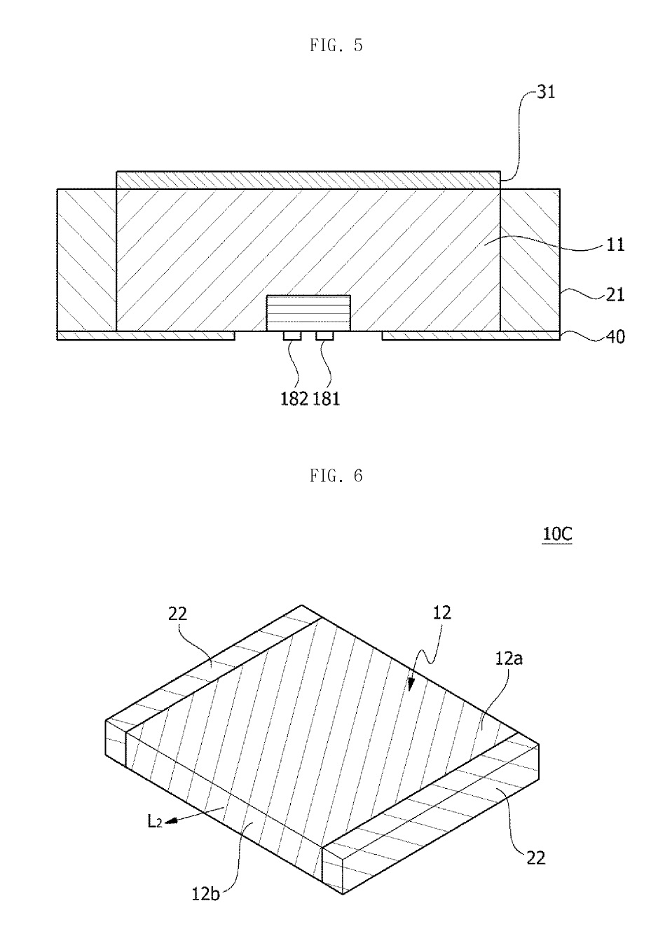

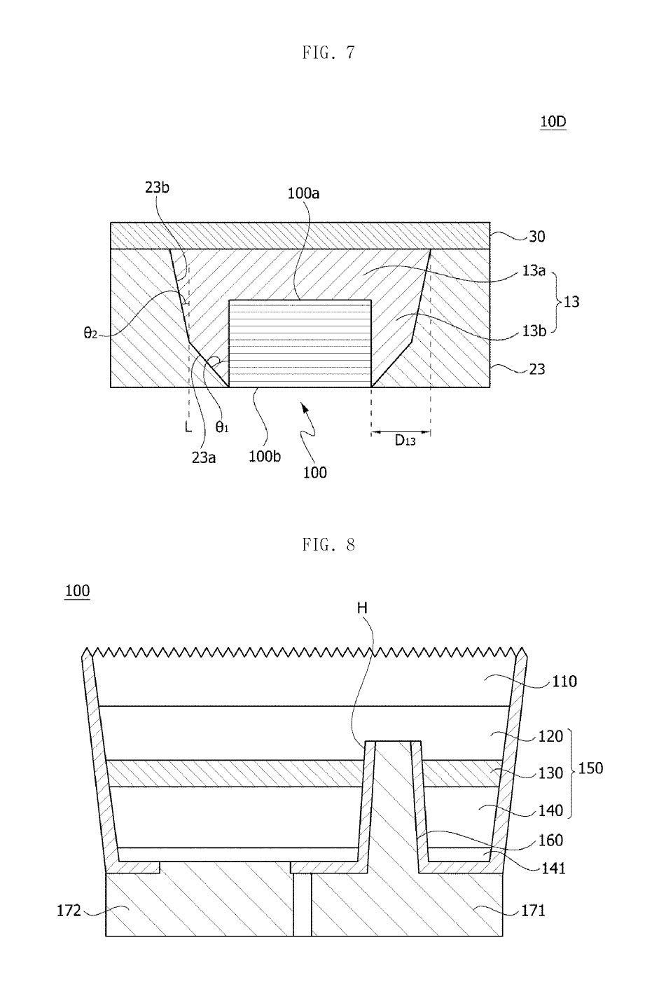

FIG. 4 is a cross-sectional view illustrating a light emitting element package according to a second exemplary embodiment of the present invention, and FIG. 5 is a view illustrating a modified example of the emitting element package of FIG. 4.

Referring to FIG. 4, a light emitting element package 10B according to the exemplary embodiment includes a light emitting element 100, a wavelength conversion layer 11 disposed on one surface and side surfaces of the light emitting element 100, and a reflective wall 21 disposed on the side surfaces of the wavelength conversion layer 11.

The wavelength conversion layer 11 may have a first region 11a disposed on the one surface of the light emitting element 100 and second regions 11b disposed on the side surfaces of the light emitting element 100. The second region 11b may have a thickness greater than or equal to a thickness of the first region 11a.

The first region 11a may convert first light L1 emitted from an upper portion of the light emitting element 100 into white light, and the second region 11b may form a channel through which second light L2 emitted from the side surfaces of the light emitting element 100 is emitted upward. The second light L2 may be reflected between the light emitting element 100 and the reflective wall 21 and then be emitted upward, and thus an orientation angle may be controlled and light extraction efficiency may be improved. Here, the second light L2 may be converted into white light while passing through the second region 11b, but the present invention is not necessarily limited thereto.

The thickness of the first region 11a may be in a range of 0.05 mm to 0.1 mm, and a thickness D11 of the second region 11b may be 0.1 mm or more. When the thickness of the second region 11b is 0.1 mm or more, it is possible to maintain a sufficient binding force between the second region 11b and the reflective wall 21. In addition, the second light L2 emitted from the side surfaces of the light emitting element may be effectually emitted upward.

Here, a thickness D21 of the reflective wall may be greater than the thickness of the first region and/or the thickness of the second region 11b.

Referring to FIG. 5, the wavelength conversion layer 11 may have a size greater than a size of the light emitting element 100. According to such a configuration, it is possible to effectively remove a dark portion between a plurality of light emitting element packages. Here, a separate supporting pad 40 may be further provided to support a lower portion of the wavelength conversion layer 11 and a lower portion of the reflective wall 21.

A protective layer 31 may be further formed on the wavelength conversion layer 11. The protective layer 31 may be formed as a layer that is optically transparent and has insulation properties. In an example, the protective layer 31 may include at least one selected from SiO2, SiON, and ITO, but the present invention is not necessarily limited thereto.

FIG. 6 is a perspective view illustrating a light emitting element package according to a third exemplary embodiment of the present invention.

Referring to FIG. 6, a light emitting element package 10C according to the exemplary embodiment is different from the above-described second embodiment in that a reflective wall 22 exposes one side surface 12b of a wavelength conversion layer 12. According to such a configuration, since light L2 is emitted from the one side surface 12b of the wavelength conversion layer 12, it is possible to enhance an orientation angle of the light emitting element package 10C. FIG. 6 shows that short sides of the wavelength conversion layer 12 are covered by the reflective wall 22 and long sides thereof are exposed. However, the reflective wall 22 may be positioned to cover the long sides.

FIG. 7 is a cross-sectional view illustrating a light emitting element package according to a fourth exemplary embodiment of the present invention.

Referring to FIG. 7, a light emitting element package 10D according to the present exemplary embodiment includes a light emitting element 100 including electrode pads disposed on one surface 100b thereof, a wavelength conversion layer 13 covering the other surface and side surfaces of the light emitting element 100, and a reflective wall 23 covering the side surfaces of the wavelength conversion layer 13.

The wavelength conversion layer 13 may have a first region 13a covering the one surface of the light emitting element 100 and second regions 13b covering the side surfaces of the light emitting element 100. A thickness D13 of the second region 13B may be gradually increased from the one surface 100b of the light emitting element 100 to the other surface 100a thereof.

Conversely, the reflective wall 23 may be gradually thinner from the one surface 100b of the light emitting element 100 to the other surface 100a. Thus, light emitted from the side surfaces of the light emitting element 100 may be reflected upward to improve light extraction efficiency.

The reflective wall 23 may have a lower inclined surface 23a having a first inclination angle θ1 and an upper inclined surface 23b having a second inclination angle θ2.

The first inclination angle θ1 may be greater than the second inclination angle θ2. According to such a configuration, it is possible to improve light extraction efficiency of side surface light. A boundary between the lower inclined surface 23a and the upper inclined surface 23b may be placed at a middle point of a thickness of the light emitting element 100. The first inclination angle θ1 and the second inclination angle θ2 may be defined as angles formed by a virtual line L and the inclined surfaces. The virtual line L may be parallel to an optical axis of the light emitting element 100.

The first inclination angle θ1 may be in a range of 10° to 60°, and the second inclination angle θ2 may be in a range of 10° to 60°. However, the first inclination angle θ1 and the second inclination angle θ2 are not necessarily limited thereto. In addition, the first inclination angle θ1 may be equal to the second inclination angle θ2.

The following Table 1 shows measurement results of color coordinates, luminous fluxes, and the like of an existing CSP (Comparative Example) not including a reflective wall, the light emitting element package according to the first exemplary embodiment, the light emitting element package according to the second exemplary embodiment, and the light emitting element package according to the third exemplary embodiment.

TABLE 1

| | | | | | | Relative |
|---|---|---|---|---|---|---|
| | | | | Luminous | | Luminous |
| | Cx | Cy | VF [V] | Flux [lm] | Lm/W | Flux |
| Comparative | 0.287 | 0.277 | 2.92 | 77.4 | 132.5 | 100% |
| Example | | | | | | |
| First | 0.286 | 0.277 | 2.92 | 64.3 | 110.1 | 83% |
| Exemplary | | | | | | |
| Embodiment | | | | | | |
| Second | 0.284 | 0.270 | 2.92 | 67.3 | 117.1 | 88% |
| Exemplary | | | | | | |
| Embodiment | | | | | | |
| Third | 0.286 | 0.274 | 2.93 | 70.9 | 122.4 | 92% |
| Exemplary | | | | | | |
| Embodiment | | | | | | |

Referring to Table 1, it can be seen that a luminous flux of the second exemplary embodiment is higher than the first exemplary embodiment. The reason for this is considered to be because of side surface light being emitted upward through the second region of the wavelength conversion layer.

As measurement results of orientation angles, in the case of Comparative Example, a long axis was measured and had an orientation angle of 136° and a short axis was measured and had an orientation angle of 154°. In the case of the first exemplary embodiment, a long axis was measured and had an orientation angle of 126° and a short axis was measured and had an orientation angle of 129°. In the case of the second exemplary embodiment, a long axis and a short axis were measured and had the same orientation angle of 124°. In addition, in the case of the third exemplary embodiment, a long axis was measured and had an orientation angle of 140° and a short axis was measured and had an orientation angle of 123°.

FIG. 8 is a conceptual view illustrating a light emitting element according to an exemplary embodiment.

A light emitting element 100 according to the exemplary embodiment includes a light emitting structure 150 disposed below a substrate 110 and a pair of electrode pads 171 and 172 disposed on one side of the light emitting structure 150.

The substrate 110 includes a conductive substrate or an insulating substrate. The substrate 110 may be made of a material suitable for growing a semiconductor material or being a carrier wafer. The substrate 110 may be made of at least one selected from sapphire (Al2O3), SiO2, SiC, Si, GaAs, GaN, ZnO, GaP, InP, Ge, and Ga2O3, but the present invention is not limited thereto. The substrate 110 may be removed as needed.

A buffer layer (not shown) may be further provided between a first semiconductor layer 120 and the substrate 110. The buffer layer may attenuate a lattice mismatch between the substrate 110 and the light emitting structure 150 provided on the substrate 110.

The buffer layer may have a form in which Group III elements are combined with Group V elements, or may include at least one selected from GaN, InN, AlN, InGaN, AlGaN, InAlGaN, and AlInN. The buffer layer may be doped with a dopant, but the present invention is not limited thereto.

The buffer layer may be grown as a single crystal on the substrate 110 and may improve crystallinity of the first semiconductor layer 120.

The light emitting structure 150 includes the first semiconductor layer 120, an active layer 130, and a second semiconductor layer 140. Generally, the above-described light emitting structure 150 and the substrate 110 may both be cut and divided into a plurality of pieces.

The first semiconductor layer 120 may be implemented using a III-V group or II-IV group compound semiconductor or the like, and may be doped with a first dopant. The first semiconductor layer 120 may be made of at least one material selected from semiconductor materials having an empirical formula of Inx1Aly1Ga1-x1-y1N (0≤x1≤1, 0≤y1<1, and 0≤x1+y1≤1), such as GaN, AlGaN, InGaN, and InAlGaN. The first dopant may be an n-type dopant such as Si, Ge, Sn, Se, or Te. When the first dopant is the n-type dopant, the first semiconductor layer 120 doped with the first dopant may be an n-type semiconductor layer.

The active layer 130 is a layer in which electrons (or holes) injected through the first semiconductor layer 120 meet holes (or electrons) injected through the second semiconductor layer 140. As electrons and holes are recombined and transition to a low energy level, the active layer 130 may generate light having a wavelength corresponding thereto.

The active layer 130 may have any one of a single well structure, a multi well structure, a single quantum well structure, a multi quantum well (MQW) structure, a quantum dot structure, and a quantum line structure, but a structure thereof is not limited thereto.

The second semiconductor layer 140 may be formed on the active layer 130, may be implemented using a III-V group or II-IV group compound semiconductor or the like, and may be doped with a second dopant. The second semiconductor layer 140 may be made of a semiconductor material having an empirical formula of Inx5Aly2Ga1-x5-y2N (0≤x5≤1, 0≤y2≤1, and 0≤x5+y2≤1), or may be made of a material selected from AlInN, AlGaAs, GaP, GaAs, GaAsP, and AlGaInP. When the second dopant is a p-type dopant such as Mg, Zn, Ca, Sr, or Ba, the second semiconductor layer 140 doped with the second dopant may be a p-type semiconductor layer.

An electron blocking layer (EBL) may be disposed between the active layer 130 and the second semiconductor layer 140. The EBL may block electrons supplied by the first semiconductor layer 120 from flowing into the second semiconductor layer 140, and thus may increase the likelihood of recombination between electrons and holes in the active layer 130. An energy band gap of the EBL may be wider than an energy band gap of the active layer 130 and/or an energy band gap of the second semiconductor layer 140.

The EBL may be made of at least one selected from semiconductor materials having an empirical formula of Inx1Aly1Ga1-x1-y1N (0≤x1≤1, 0≤y1≤1, and 0≤x1+y1≤1), such as GaN, AlGaN, InGaN, and InAlGaN, but is not limited thereto.

The light emitting layer 150 has a through-hole H formed in a direction from the second semiconductor layer 140 to the first semiconductor layer 120. An insulation layer 160 may be formed on side surfaces of the light emitting layer 150 and the through-hole H. Here, the insulation layer 160 may expose one surface of the second semiconductor layer 140.

An electrode layer 141 may be disposed on the one surface of the second semiconductor layer 140. The electrode layer 141 may include at least one selected from indium tin oxide (ITO), indium zinc oxide (IZO), indium zinc tin oxide (IZTO), indium aluminum zinc oxide (IAZO), indium gallium zinc oxide (IGZO), indium gallium tin oxide (IGTO), aluminum zinc oxide (AZO), antimony tin oxide (ATO), gallium zinc oxide (GZO), IrOx, RuOx, RuOx/ITO, Ni/IrOx/Au, and Ni/IrOx/Au/ITO, but is not limited thereto.

In addition, the electrode layer 141 may further include a metal layer including any one selected from In, Co, Si, Ge, Au, Pd, Pt, Ru, Re, Mg, Zn, Hf, Ta, Rh, Ir, W, Ti, Ag, Cr, Mo, Nb, Al, Ni, Cu, and WTi.

A first electrode pad 171 may be electrically connected to the first semiconductor layer 120. Specifically, the first electrode pad 171 may be electrically connected to the first semiconductor layer 120 through the through-hole H. The first electrode pad 171 may be electrically connected to a first solder bump 181.

A second electrode pad 172 may be electrically connected to the second semiconductor layer 140. Specifically, the second electrode pad 172 may be formed to pass through the insulation layer to be electrically connected to the electrode layer 141. The second electrode pad 172 may be electrically connected to a second solder bump 182.

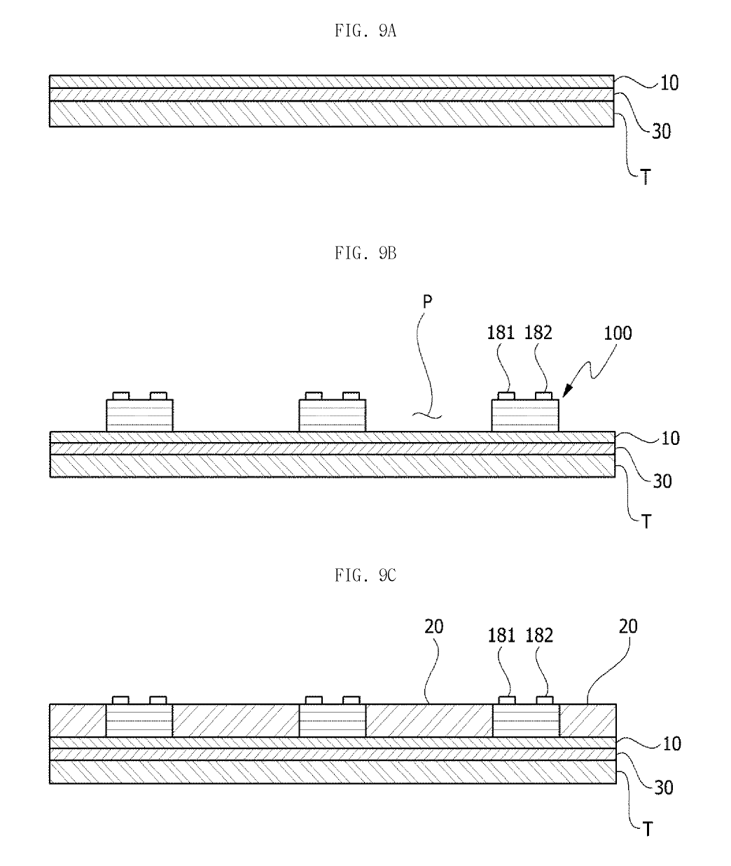

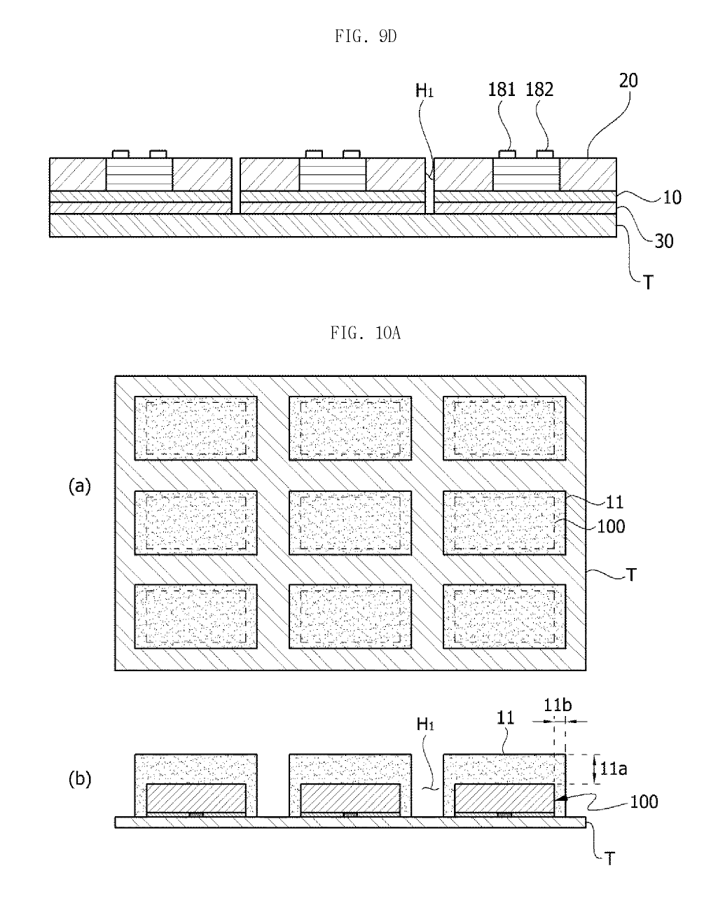

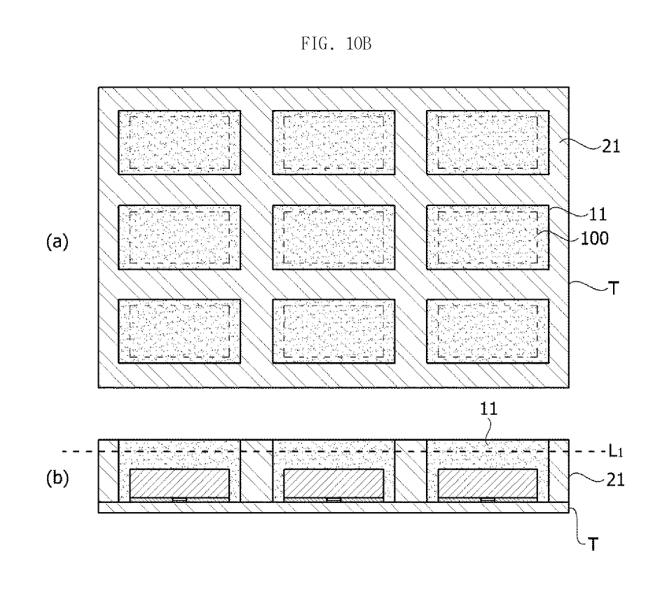

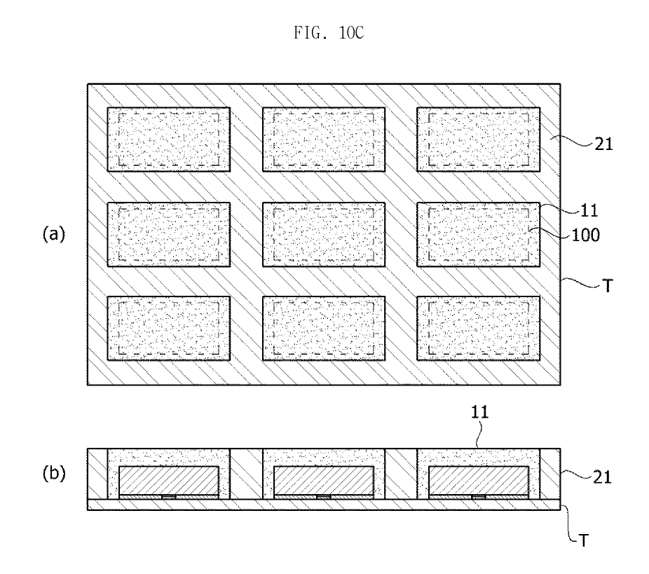

FIGS. 9A to 9D are a flowchart of a method of manufacturing the light emitting element package according to the first exemplary embodiment of the present invention.

The method of manufacturing the light emitting element package according to the first exemplary embodiment includes forming a wavelength conversion layer on a fixed substrate, forming a reflective wall between a plurality of light emitting elements, and manufacturing a plurality of light emitting element packages by cutting the reflective wall and the wavelength conversion layer.

Referring to FIG. 9A, in the forming of the wavelength conversion layer, a wavelength conversion material may be applied on a fixed substrate T. In this case, a diffusion layer 30 may be primarily formed on the fixed substrate T. The fixed substrate T may be a UV tape, but is not limited thereto. The wavelength conversion material may be a resin in which a fluorescent material is dispersed, and a wavelength conversion layer 10 may be formed by curing the wavelength conversion material.

Referring to FIGS. 9B and 9C, in the forming of the reflective wall, a plurality of light emitting elements 100 may be disposed on the wavelength conversion layer 10 at certain intervals. In this case, the light emitting elements 100 may each be a flip chip including electrode pads 181 and 182 disposed on another surface thereof

A reflective material may be applied in a space P between the light emitting elements 100. The reflective material may be silicone in which TiO2 and the like is dispersed. Phenyl silicone having relatively high hardness may be selected to perform a transferring process. Then, a reflective wall 20 is formed by curing the reflective material.

Referring to FIG. 9D, in the manufacturing of the light emitting element packages, the plurality of light emitting element packages may be manufactured by cutting (H1) the wavelength conversion layer 10 and the reflective wall 20. In this case, the transferring process may be further performed on other adhesive tapes as needed.

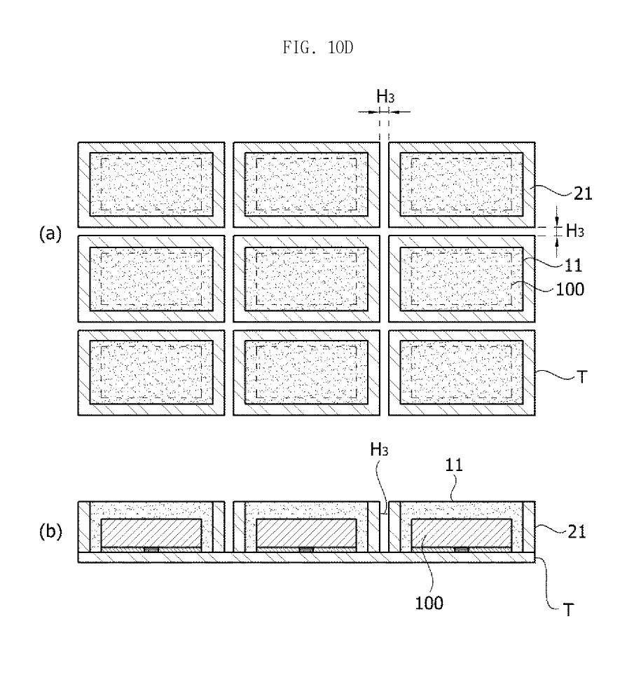

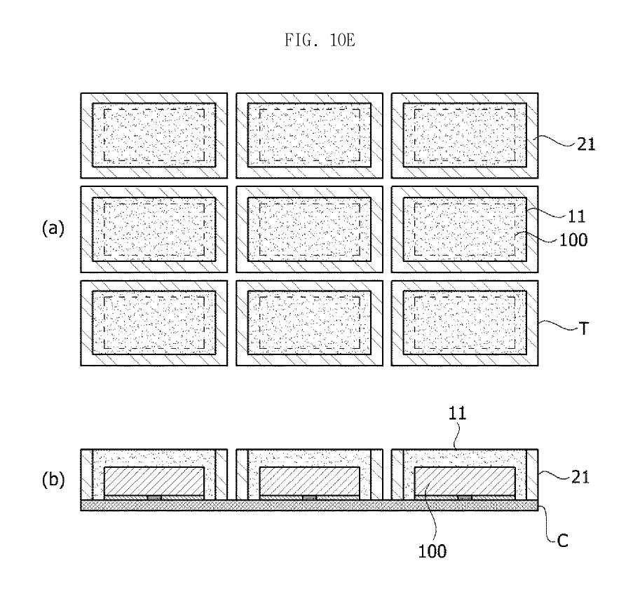

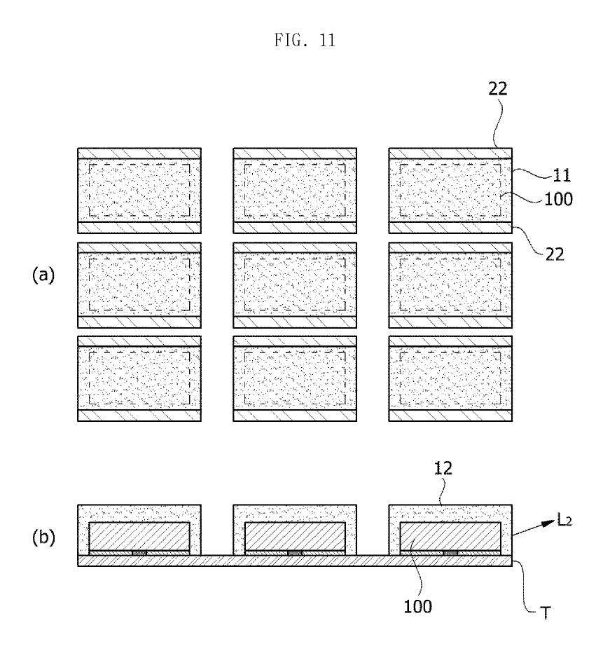

FIGS. 10A to 10E are a flowchart of a method of manufacturing the light emitting element package according to the second exemplary embodiment of the present invention. FIGS. 10A(A) to 10E(A) are plan views, and FIGS. 10A(B) to 10E(B) are cross-sectional views.

The method of manufacturing the light emitting element package according to the second exemplary embodiment includes disposing a plurality of light emitting elements on a fixed substrate, forming a wavelength conversion layer on one surface and side surfaces of each of the plurality of light emitting elements, forming grooves by cutting between the wavelength conversion layers, forming a reflective wall in the grooves, and manufacturing a plurality of light emitting element packages by cutting the reflective wall.

Referring to FIG. 10A, in the disposing of the plurality of light emitting elements on the fixed substrate, light emitting elements 100 may be disposed on a fixed substrate T at certain intervals. The fixed substrate T may be a UV tape, and the light emitting elements 100 may be a flip chip.

In the forming of the wavelength conversion layer, the wavelength conversion layer may be formed by applying a wavelength conversion material onto one surface and side surfaces of each of the plurality of light emitting elements and curing the applied wavelength conversion material. A thickness of the first region 11a of a wavelength conversion layer 11 may be greater than a thickness of the second region 11b thereof. Then, grooves H1 are formed by cutting the wavelength conversion layer filling a space between the light emitting elements.

Referring to FIGS. 10B and 10C, in the forming of the reflective wall, a reflective wall 21 may be formed by a reflective material being filled in the grooves. The reflective material may be silicone in which TiO2 and the like are dispersed. Phenyl silicone having relatively high hardness may be selected to perform a transferring process. In this case, a leveling operation may be performed to lower the wavelength conversion layer to an appropriate height L1.

Referring to FIG. 10D, in the manufacturing of the light emitting element packages, the plurality of light emitting element packages may be manufactured by removing portions H3 of the reflective wall 21.

Referring to FIG. 10E, UV light may be emitted toward the fixed substrate T to remove a binding force of the fixed substrate T and exfoliate the fixed substrate T, and a separate adhesive tape C may then be attached thereto (a transferring process). The adhesive tape C may have a low adhesive force when compared to a UV tape. Therefore, the manufactured light emitting element packages may be individually separated.

FIG. 11 is a view illustrating a method of manufacturing the light emitting element package according to the third exemplary embodiment of the present invention.

Referring to FIG. 11, the light emitting element package according to the third exemplary embodiment is different from the second exemplary embodiment in that a reflective wall 22 is formed only on one side surface of a wavelength conversion layer 12. That is, in the second exemplary embodiment, the reflective wall is formed on all of four side surfaces of the wavelength conversion layer, whereas some side surfaces are open to enhance an orientation angle in the present exemplary embodiment.

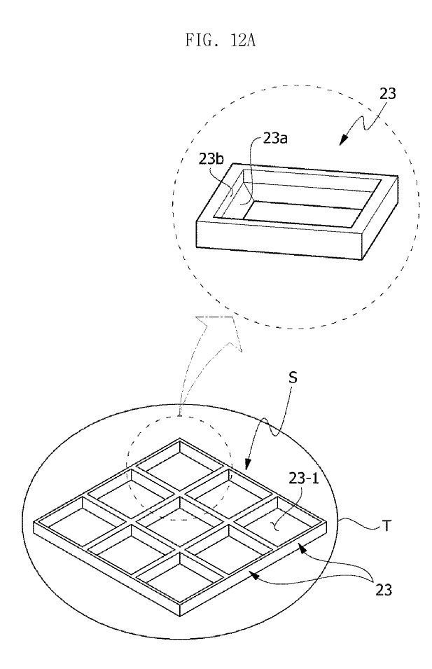

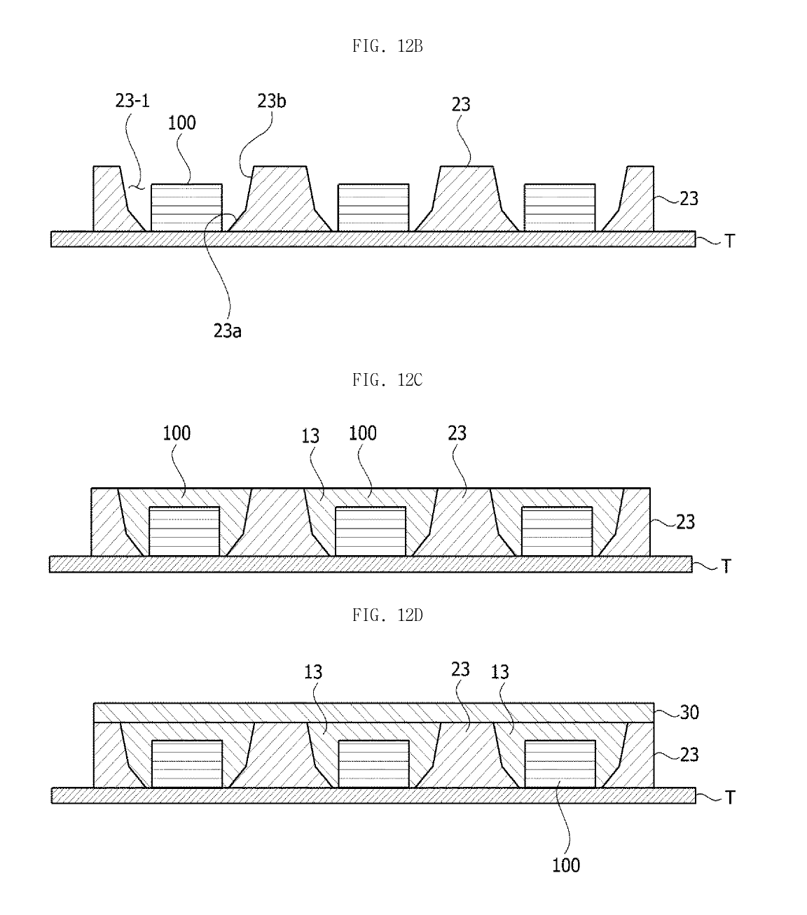

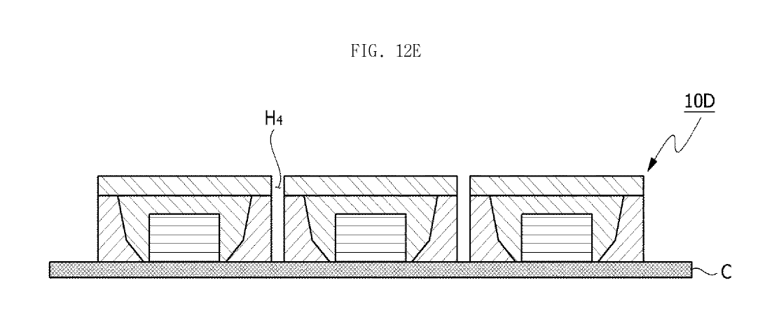

FIGS. 12A to 12E are a flowchart of a method of manufacturing the light emitting element package according to the fourth exemplary embodiment of the present invention.

Referring to FIG. 12, the method of manufacturing a light emitting element package according to the fourth exemplary embodiment includes attaching a reflective plate including a plurality of reflective walls to a fixed substrate, arranging a light emitting element in each of the reflective walls, injecting a wavelength conversion material into each of the reflective walls, and manufacturing a plurality of light emitting element packages by separating the reflective walls.

Referring to FIG. 12A, in the attaching of the reflective plate to the fixed substrate, a reflective plate S may be attached to a fixed substrate T. The reflective plate S may have a structure in which a plurality of reflective walls 23 are connected. Each of the reflective walls 23 may have an inner inclined surface, and an inclination angle thereof may change an inclination angle formed by the lower inclined surface 23a and the upper inclined surface 23b at a certain height.

Referring to FIG. 12B, in the arranging of the light emitting element, a light emitting element 100 is disposed in an inner space 23-1 of each of the reflective walls 23. The light emitting element 100 may be attached to the fixed substrate T. The light emitting element 100 may be a flip chip, and electrode pads may be attached to the fixed substrate T.

Referring to FIG. 12C, in the injecting of the wavelength conversion material, a wavelength conversion layer 13 is formed by injecting the wavelength conversion material into the inner space 23-1 of each of the reflective walls 23 and curing the injected wavelength conversion material. Then, a height of the wavelength conversion layer may be appropriately adjusted through a leveling process. A diffusion layer 30 may be additionally formed as shown in FIG. 12D.

Referring to FIG. 12E, in the manufacturing of the plurality of light emitting element packages, the plurality of light emitting element packages may be manufactured by cutting (H4) the reflective walls 23.

A light emitting element package according to the exemplary embodiments may further include optical members, such as a light guide plate, a prism sheet, and a diffusion sheet, to function as a backlight unit. In addition, the light emitting element package according to the exemplary embodiments may be further applied to a display device, a lighting device, and an indicating device.

Here, the display device may include a bottom cover, a reflective plate, a light emitting module, a light guide plate, an optical sheet, a display panel, an image signal output circuit, and a color filter. The bottom cover, the reflective plate, the light emitting module, the light guide plate, and the optical sheet may constitute a backlight unit.

The reflective plate is disposed on the bottom cover, and the light emitting module emits light. The light guide plate is disposed in front of the reflective plate and guides light emitted from the light emitting module in a forward direction, and the optical sheet includes a prism sheet and the like and is disposed in front of the light guide plate. The display panel is disposed in front of the optical sheet, the image signal output circuit supplies an image signal to the display panel, and the color filter is disposed in front of the display panel.

The lighting device may include a substrate, a light source module including the light emitting element package according to the exemplary embodiments, a heat dissipater for dissipating heat of the light source module, and a power supply for processing or converting an electrical signal supplied from the outside and supplying the processed or converted electrical signal to the light source module. In addition, the lighting device may include a lamp, a head lamp, a street lamp, or the like.

Furthermore, a camera flash of a mobile terminal may include a light source module including the light emitting element package according to the exemplary embodiments. As described above, since the light emitting element package has an orientation angle corresponding to a FOV of a camera, it is possible to reduce light loss.

The above-described present invention is not limited to the above-described exemplary embodiments and the drawings, and it should be apparent to those skilled in the art that various substitutions, modifications, and variations are possible within a range that does not depart from the technical idea of the exemplary embodiment.

1. A light emitting element package comprising:
a light emitting element comprising a first electrode pad and a second electrode pad disposed on one surface thereof;
a wavelength conversion layer disposed on the other surface of the light emitting element; and
a reflective wall disposed on a side surface of the light emitting element,
wherein the reflective wall is in contact with the side surface of the light emitting element, and the first electrode pad and the second electrode pad are exposed to the outside.

2. The light emitting element package of claim 1, wherein the wavelength conversion layer is disposed on the reflective wall.

3. The light emitting element package of claim 2, wherein the reflective wall has a first surface in contact with the wavelength conversion layer and a second surface opposite the first surface.

4. The light emitting element package of claim 3, wherein the second surface is convex toward the first surface.

5. The light emitting element package of claim 1, further comprising a diffusion layer disposed on the wavelength conversion layer.

6. The light emitting element package of claim 1, wherein:
a width in a second direction of the reflective wall is greater than a width in a first direction of the wavelength conversion layer;
the first direction is parallel to a thickness direction of the light emitting element; and
the second direction is perpendicular to the first direction.

7. The light emitting element package of claim 1, wherein:
a width in a first direction of the reflective wall is greater than a width in the first direction of the wavelength conversion layer; and
the first direction is parallel to a thickness direction of the light emitting element.

8. The light emitting element package of claim 1, wherein the reflective wall is in contact with a side surface of the wavelength conversion layer.

9. The light emitting element package of claim 2, wherein an uneven portion is formed on a contact surface between the wavelength conversion layer and the reflective wall.

10. The light emitting element package of claim 1, wherein the wavelength conversion layer has a thickness of 0.05 mm to 0.1 mm.

11. The light emitting element package of claim 1, wherein the reflective wall has a thickness of 0.2 mm to 0.5 mm.

12. The light emitting element package of claim 1, wherein the reflective wall comprises phenyl silicone or methyl silicone.

13. The light emitting element package of claim 12, wherein the reflective wall comprises reflective particles.

14. A light emitting element package comprising:
a light emitting element comprising a first electrode pad and a second electrode pad disposed on one surface thereof;
a wavelength conversion layer disposed on the other surface and a side surface of the light emitting element; and
a reflective wall disposed on a side surface of the wavelength conversion layer,
wherein the first electrode pad and the second electrode pad are exposed to the outside.

15. The light emitting element package of claim 14, wherein a side thickness of the wavelength conversion layer is gradually increased from the one surface of the light emitting element to the other surface thereof.

16. The light emitting element package of claim 14, wherein the reflective wall is gradually thinner from the one surface of the light emitting element to the other surface thereof.

17. The light emitting element package of claim 14, wherein the reflective wall has an inclined surface formed on an inner peripheral surface thereof.

18. The light emitting element package of claim 14, wherein the reflective wall has a lower inclined surface having a first inclination angle and an upper inclined surface having a second inclination angle.

19. The light emitting element package of claim 18, wherein the first inclined angle is greater than the second inclined angle.

20. The light emitting element package of claim 18, wherein the first inclined angle is equal to the second inclined angle.
